(19) United States
(12) Patent Application Publication
(10) Pub. No.: US 2018/0226465 A1
(43) Pub. Date: Aug. 9, 2018

(54) WIRING STRUCTURE, ARRAY SUBSTRATE AND MANUFACTURING METHOD THEREOF, AND DISPLAY PANEL

(71) Applicant: Boe Technology Group Co., Ltd., Beijing (CN)

(72) Inventor: Kun CAO, Beijing (CN)

(73) Assignee: Boe Technology Group Co., Ltd., Beijing (CN)

(21) Appl. No.: 15/570,712

(22) PCT Filed: Apr. 24, 2017
(86) PCT No.: PCT/CN2017/081633

§ 371 Date: Oct. 30, 2017

(30) Foreign Application Priority Data
Jun. 1, 2016 (CN) 201610383827.4

(51) Int. Cl. H01L 27/32; H01L 51/52

(52) U.S. Cl. CPC H01L 27/3276; H01L 51/5203

(57) ABSTRACT

The embodiments of the invention provide a wiring structure, an array substrate and manufacturing method thereof, and a display panel, relate to the field of display technology, and can reduce the resistance of the wiring structure while reducing the wire width of the wiring structure. The wiring structure includes a first metal wire and a second metal wire disposed in a stack; wherein the first metal wire and the second metal wire are in direct contact.

### RELATED APPLICATIONS

The present application claims the benefit of Chinese Patent Application No. 201610383827.4, filed on Jun. 1, 2016, the entire disclosures of which are incorporated herein by reference.

### TECHNICAL FIELD

The invention relates to the field of display technology, in particular to a wiring structure, an array substrate and manufacturing method thereof, and a display panel.

### BACKGROUND

With the rapid development of display technology, the display panel has been applied to display devices with various sizes. In addition to the requirement of good display performance for the display panel, consumers' pursuit of the appearance has also gradually increased. The narrow frame display panel, which makes the display panel thinner and smaller, has become one of the goals pursued by consumers.

At present, to realize the narrow frame of the display panel, the distribution area of the wiring structure is reduced by reducing the wire width of the wiring structure on the periphery of the display panel, thereby reducing the width of the frame. However, reducing of the wire width of the wiring structure will make the resistance of the wiring structure become larger, so it is disadvantageous for signal conduction.

### SUMMARY

The embodiments of the invention provide a wiring structure, an array substrate and manufacturing method thereof, and a display panel, which can reduce the resistance of the wiring structure while reducing the wire width of the wiring structure.

In order to achieve the above object, the embodiments of the invention adopt the following technical solutions.

According to a first aspect, a wiring structure is provided. The wiring structure includes a first metal wire and a second metal wire disposed in a stack, wherein the first metal wire and the second metal wire are in direct contact.

Optionally, the wire widths of the first metal wire and the second metal wire are the same, and the projections of the first metal wire and the second metal wire in a plane perpendicular to the stacking direction are completely overlapped.

Further optionally, the wire widths of the first metal wire and the wire width of the second metal wire are both 5˜50 μm.

Optionally, the materials of the first metal wire and the second metal wire are selected from at least one of single metal, alloy, and metal oxide.

According to a second aspect, an array substrate is provided. The array substrate includes the above described wiring structure.

Optionally, the array substrate further includes an insulating layer, wherein the first metal wire and the insulating layer are disposed in the same layer.

Optionally, the wiring structure is disposed in a peripheral region of the array substrate.

Optionally, the array substrate includes a thin film transistor and a first electrode. The first metal wire and the second metal wire are formed in synchronism with the thin film transistor. Alternatively, the first metal wire and the second metal wire are formed in synchronism with the thin film transistor and the first electrode.

Optionally, the array substrate includes a thin film transistor, a pixel electrode and a common electrode. The first metal wire and the second metal wire are formed in synchronism with the thin film transistor and the common electrode. Alternatively, the first metal wire and the second metal wire are formed in synchronism with the pixel electrode and the common electrode.

According to a third aspect, a display panel is provided, which includes the above described array substrate.

According to a fourth aspect, a method for manufacturing the array substrate is provided. The method includes the following steps: forming a first metal pattern, a region of the first metal pattern corresponding to a region where wiring structures are to be formed; forming an insulating layer, and removing the material of the insulating layer on the first metal pattern by an etching process; forming a second metal pattern, and forming a plurality of wiring structures by an etching process, each of the wiring structure including a first metal wire and a second metal wire stacked together.

Optionally, the step of forming a first metal pattern includes: forming a first metal layer, and performing an etching process on the first metal layer to form the first metal pattern.

The embodiments of the invention provide a wiring structure, an array substrate and manufacturing method thereof, and a display panel. Since the wiring structure includes the first metal wire and the second metal wire stacked together, the increase in the resistance of the wiring structure is small even if the wire width of the wiring structure is reduced. On this basis, the contact resistance between the first metal wire and the second metal wire can be greatly reduced due to the direct contact of the first metal wire and the second metal wire, thereby further reducing the resistance of the wiring structure. Thus, the embodiments of the invention can reduce the resistance of the wiring structure while reducing the wire width of the wiring structure.

### BRIEF DESCRIPTION OF THE DRAWINGS

In order to more clearly illustrate the technical solutions in embodiments of the invention or in the prior art, the appended drawings needed to be used in the description of the embodiments or the prior art will be introduced briefly in the following. Obviously, the drawings in the following description are only some embodiments of the invention, and for those of ordinary skills in the art, other drawings may be obtained according to these drawings under the premise of not paying out creative work.

FIG. 1 is a structural schematic diagram of a wiring structure provided by an embodiment of the invention;

FIG. 2 is a structural schematic diagram of an array substrate including a wiring structure provided by an embodiment of the invention;

FIG. 3 is a flow chart of a method for manufacturing an array substrate provided by an embodiment of the invention;

FIG. 4(a) is a structural schematic diagram of forming a first metal pattern provided by an embodiment of the invention;

FIG. 4(b) is a structural schematic diagram of forming an insulating layer on the first metal pattern provided by an embodiment of the invention;

FIG. 4(c) is a structural schematic diagram of removing the insulating layer on the first metal pattern provided by an embodiment of the invention;

FIG. 4(d) is a structural schematic diagram of forming a second metal pattern on the first metal pattern provided by an embodiment of the invention; and

FIG. 4(e) is a structural schematic diagram of forming a first metal wire and a second metal wire provided by an embodiment of the invention.

Reference signs: 01-wiring structure; 10-first metal wire; 101-first metal pattern; 20-second metal wire; 102-second metal pattern; 30-substrate; 40-insulating layer.

### DETAILED DESCRIPTION OF THE INVENTION

In the following, the technical solutions in the embodiments of the invention will be described clearly and completely in connection with the drawings in the embodiments of the invention. Obviously, the described embodiments are only part of the embodiments of the invention, and not all of the embodiments. Based on the embodiments in the invention, all other embodiments obtained by those of ordinary skills in the art under the premise of not paying out creative work pertain to the protection scope of the invention.

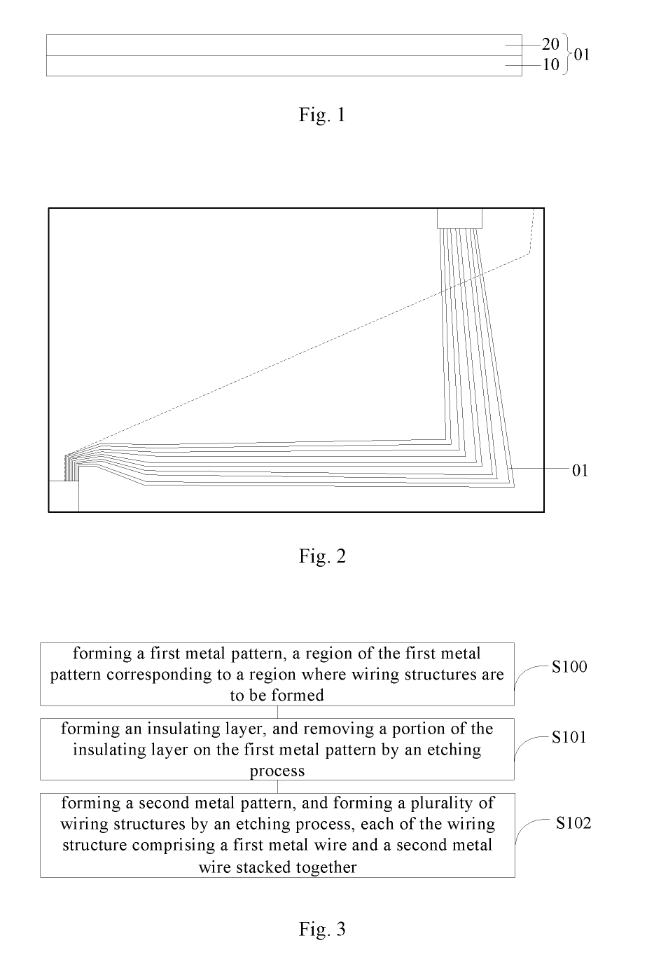

An embodiment of the invention provides a wiring structure 01, as shown in FIG. 1 and FIG. 2. FIG. 1 shows a local cross-sectional view of the wiring structure 01 in FIG. 2. The wiring structure 01 includes a first metal wire 10 and a second metal wire 20 disposed in a stack, wherein the first metal wire 10 and the second metal wire 20 are in direct contact.

It should be noted that, firstly, the materials of the first metal wire 10 and the second metal wire 20 are not limited as long as the signal can be conducted. The material of the first metal wire 10 can be the same as the material of the second metal wire 20. Of course, the material of the first metal wire 10 and the material of the second metal wire 20 can also be different.

Secondly, the wire widths of the first metal wire 10 and the wire width of the second metal wire 20 can be the same or different.

When the wire widths of the first metal wire 10 and the wire width of the second metal wire 20 are different, the first metal wire 10 can be formed by a composition process first, and then the second metal wire 20 can be formed by a composition process. Herein, since the first metal wire 10 is manufactured first, in order to ensure that the first metal wire 10 and the second metal wire 20 are in contact with each other when the second metal wire 20 is manufactured, optionally, the wire width of the wire 10 is greater than the wire width of the second metal wire 20. When the wire width of the first metal wire 10 and the wire width of the second metal wire 20 are the same, the first metal wire 10 and the second metal wire 20 can be formed simultaneously by a composition process.

Thirdly, the first metal wire 10 and the second metal wire 20 are in direct contact, i.e. the first metal wire 10 and the second metal wire 20 are in close contact and are in electrical contact, and no film is disposed between the first metal wire 10 and the second metal wire 20.

In the wiring structure 01 provided by the embodiments of the invention, since the wiring structure includes the first metal wire 10 and the second metal wire 20 stacked together, the increase in the resistance of the wiring structure 01 is small even if the wire width of the wiring structure 01 is reduced. On this basis, the contact resistance between the first metal wire 10 and the second metal wire 20 can be greatly reduced due to the direct contact of the first metal wire 10 and the second metal wire 20, thereby further reducing the resistance of the wiring structure 01. Thus, the embodiment of the invention can reduce the resistance of the wiring structure 01 while reducing the wire width of the wiring structure

Optionally, as shown in FIG. 1, the wire widths of the first metal wire 10 and the second metal wire 20 are the same, and the projections of the first metal wire 10 and the second metal wire 20 in a plane perpendicular to the stacking direction are completely overlapped.

In the embodiments of the invention, the wire widths of the first metal wire 10 and the second metal wire 20 are the same, and the projections of the first metal wire 10 and the second metal wire 20 in a plane perpendicular to the stacking direction are completely overlapped, so that the first metal wire 10 and the second metal wire 20 can be formed simultaneously by a one-time composition process, which simplified the manufacture process of the first metal wire 10 and the second metal wire 20. Further, the wire widths of the first metal wire 10 and the second metal wire 20 are the same, and the projections of the first metal wire 10 and the second metal wire 20 in a plane perpendicular to the stacking direction are completely overlapped, so that the first metal wire 10 and the second metal wire 20 can be directly aligned. Therefore, there is no need for reserving a certain interval between the wiring structures 01 (each wiring structure 01 including a first metal wire 10 and a second metal wire 20) to ensure alignment accuracy between the first metal wiring 10 and the second metal wire 20. Thus, the interval between the wiring structures 01 of the embodiment of the invention can be set to be smaller, thereby reducing the distribution area of the wiring structures 01.

If the wire widths of the first metal wire 10 and the second metal wire 20 are too small, it may result in a failure of signal conducting. If the wire widths of the first metal wire 10 and the second metal wire 20 are too large, the distribution area of the wiring structures 01 may be large. Thus, in order to ensure that the first metal wire 10 and the second metal wire 20 can not only conduct signals but also reduce the distribution area of the wiring structures 01, optionally, the wire widths of the first metal wire 10 and the second metal wire 20 are both 5˜50 μm.

Optionally, the materials of the first metal wire 10 and the second metal wire 20 are selected from at least one of single metal, alloy, and metal oxide. For example, Mo (molybdenum), Cu (copper), Ag (silver) or IZO (indium zinc oxide), etc. can be used.

An embodiment of the invention provides an array substrate including the above described wiring structure.

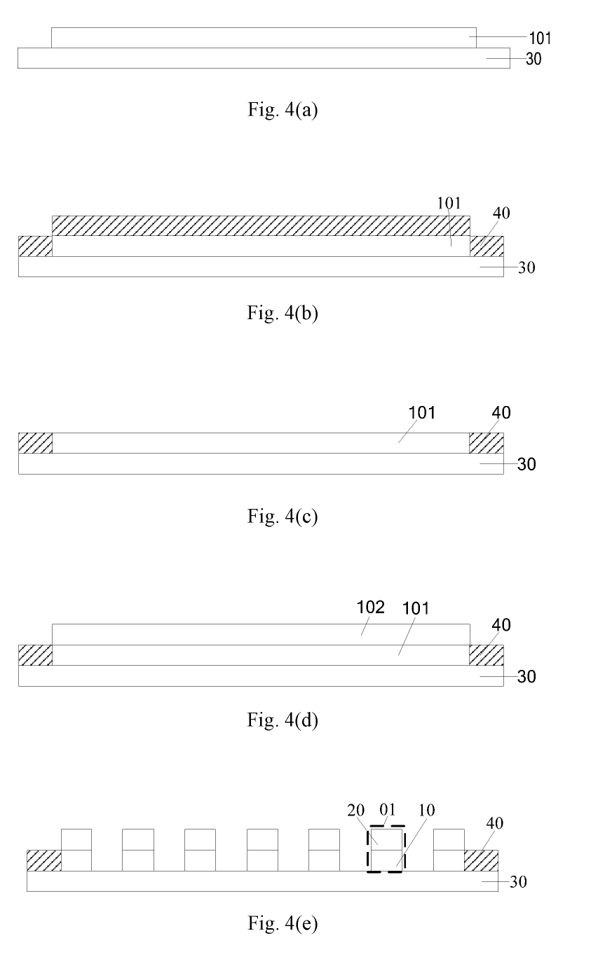

Optionally, as shown in FIG. 4(e), the array substrate further includes an insulating layer 40, wherein the first metal wire 10 and the insulating layer 40 are disposed in the same layer.

The number of the wiring structure(s) 01 on the array substrate is not limited, and the number can be set according to the signal to be conducted on the array substrate.

In the manufacture process of the array substrate, after forming the first metal wire 10 and display elements which are in the same layer with the first metal wire 10, due to the process reasons, the insulating layer should be formed on the first metal wire 10 and the display elements which are in the same layer with the first metal wire 10. In order to ensure that the first metal wire 10 and the second metal wire 20 are in direct contact, it is necessary to remove the insulating layer formed on the first metal wire 10, so that the insulating layer between the first metal wire 10 and the second metal wire 20 is hollowed-out.

In the array substrate provided by the embodiments of the invention, since the wiring structure 01 of the array substrate includes the first metal wire 10 and the second metal wire 20 stacked together, the increase in the resistance of the wiring structure 01 is small even if the wire width of the wiring structure 01 is reduced. On this basis, the contact resistance between the first metal wire 10 and the second metal wire 20 can be greatly reduced due to the direct contact of the first metal wire 10 and the second metal wire 20, thereby further reducing the resistance of the wiring structure 01. Thus, the embodiment of the invention can reduce the resistance of the wiring structure 01 while reducing the wire width of the wiring structure 01.

Optionally, as shown in FIG. 2, the wiring structure 01 is disposed in the peripheral region of the array substrate. The intermediate region of the array substrate can be provided with display elements.

In the embodiment of the invention, the wiring structures 01 are disposed in the peripheral region of the array substrate, i.e. each wiring structure 01 in the peripheral region of the array substrate includes the first metal wire 10 and second metal wire 20 stacked together, the increase in the resistance of the wiring structure 01 is small even if the wire width of the wiring structure 01 is reduced. On this basis, the contact resistance between the first metal wire 10 and the second metal wire 20 can be greatly reduced due to the direct contact of the first metal wire 10 and the second metal wire 20, thereby further reducing the resistance of the wiring structure 01. Thus, the array substrate of the embodiment of the invention can reduce the resistance of the wiring structure 01 while reducing the wire width of the wiring structure 01.

Optionally, the array substrate includes a thin film transistor and a first electrode. The first metal wire 10 and the second metal wire 20 are formed in synchronism with the thin film transistor. Alternatively, the first metal wire 10 and the second metal wire 20 are formed in synchronism with the thin film transistor and the first electrode.

The thin film transistor includes a gate, an insulating layer, a semiconductor layer, a source and a drain. If the array substrate is an array substrate of a liquid crystal display (LCD), the first electrode is a pixel electrode, and the pixel electrode is electrically connected to the drain of the thin film transistor. Further, the array substrate can also include a common electrode. If the array substrate is an array substrate of an organic light-emitting diode (OLED) display, the first electrode is an anode, and the anode is electrically connected to the drain of the thin film transistor. Further, the array substrate can also include an organic material functional layer and a cathode.

Herein, the first metal wire 10 and the second metal wire 20 are formed in synchronism with the thin film transistor, i.e., the first metal wire 10 and the second metal wire 20 are formed in synchronism with any two of the gate, source and drain of the thin film transistor. The first metal wire 10 and the second metal wire 20 are formed in synchronism with the thin film transistor and the first electrode, i.e., the first metal wire 10 is formed in synchronism with any one of the gate, source and drain of the thin film transistor, and the second metal wire 20 is formed in synchronism with the first electrode. Alternatively, the first metal wire 10 is formed in synchronism with the first electrode, and the second metal wire 20 is formed in synchronism with any one of the gate, source and drain of the thin film transistor.

In the embodiments of the invention, the first metal wire 10 and the second metal wire 20 can be formed in synchronism with the thin film transistor. Alternatively, the first metal wire 10 and the second metal wire 20 can be formed in synchronism with the thin film transistor and the first electrode. In this way, the manufacture process of the array substrate can be simplified.

Optionally, the array substrate includes a thin film transistor, a pixel electrode and a common electrode. The first metal wire 10 and the second metal wire 20 are formed in synchronism with the thin film transistor and the common electrode. Alternatively, the first metal wire 10 and the second metal wire 20 are formed in synchronism with the pixel electrode and the common electrode.

In this embodiment, the first metal wire 10 and the second metal wire 20 are formed in synchronism with the thin film transistor and the common electrode, i.e., the first metal wire 10 is formed in synchronism with any one of the gate, source and drain of the thin film transistor, and the second metal wire 20 is formed in synchronism with the common electrode. Alternatively, the first metal wire 10 is formed in synchronism with the common electrode, and the second metal wire 20 is formed in synchronism with any one of the gate, source and drain of the thin film transistor. The first metal wire 10 and the second metal wire 20 are formed in synchronism with the pixel electrode and the common electrode, i.e., the first metal wire 10 is formed in synchronism with the pixel electrode, and the second metal wire 20 is formed in synchronism with the common electrode. Alternatively, the first metal wire 10 is formed in synchronism with the common electrode, and the second metal wire 20 is formed in synchronism with the pixel electrode.

In the embodiments of the invention, the first metal wire 10 and the second metal wire 20 can be formed in synchronism with the thin film transistor and the common electrode. Alternatively, the first metal wire 10 and the second metal wire 20 can be formed in synchronism with the first electrode and the common electrode. In this way, the manufacture process of the array substrate can be simplified.

An embodiment of the invention provides a display panel including the above described array substrate.

In the display panel provided by the embodiments of the invention, since the wiring structure 01 of the display panel includes the first metal wire 10 and the second metal wire 20 stacked together, the increase in the resistance of the wiring structure 01 is small even if the wire width of the wiring structure 01 is reduced. On this basis, the contact resistance between the first metal wire 10 and the second metal wire 20 can be greatly reduced due to the direct contact of the first metal wire 10 and the second metal wire 20, thereby further reducing the resistance of the wiring structure 01. Thus, the display panel of the embodiments of the invention can reduce the resistance of the wiring structure 01 while reducing the wire width of the wiring structure 01.

An embodiment of the invention provides a method for manufacturing an array substrate. As shown in FIG. 3, the method includes the following steps.

S100, forming a first metal pattern 101, as shown in FIG. 4(a), the region of the first metal pattern 101 corresponding to the region where the wiring structures are to be formed.

Optionally, the step of forming a first metal pattern includes the steps of: forming a first metal layer, and performing an etching process on the first metal layer to form the first metal pattern. The material of the first metal pattern 101 is not limited herein. The material of the first metal pattern 101 can be selected from at least one of single metal, alloy, and metal oxide. For example, the material can be Mo, Cu, Ag, or IZO, etc.

Herein, the first metal pattern 101 is formed on the substrate 30, and other structures on the substrate 30 are not shown in FIG. 4(a). It is not limited how the first metal pattern is formed on the substrate 30. For example, it can be formed by a chemical vapor deposition method or a vapor plating process.

S101, forming an insulating layer 40, as shown in FIG. 4(b), and removing a portion of the insulating layer 40 on the first metal pattern 101 by an etching process, as shown in FIG. 4(c).

The material of the insulating layer 40 is not limited herein. For example, the material of the insulating layer 40 can be one or more of SiN (silicon oxide) or SiO (silicon oxide), silicon oxynitride (SiOₓN_{y}) and silicon carbonitride (SiCₓN_{y}).

Herein, only a portion of the insulating layer 40 located on the first metal pattern 101 should be removed by the etching process, and the portion of the insulating layer 40 on other regions of the array substrate is reserved.

S102, forming a second metal pattern 102, as shown in FIG. 4(d), and forming a plurality of wiring structures 01 by an etching process, each of the wiring structure 01 includes the first metal wire 10 and the second metal wire 20 stacked together.

The material of the second metal pattern 102 is not limited herein. The material of the second metal pattern 102 can be selected from at least one of single metal, alloy, and metal oxide. For example, the material can be Mo, Cu, Ag, or IZO, etc. The material of the second metal pattern 102 can be the same as or different with the material of the first metal pattern 101.

The wire width and the number of the formed first metal wire 10 and the second metal wire 20 are not limited herein and can be etched according to the requirements on the array substrate. The interval between the wiring structures 01 are not limited herein, as long as the wiring structures 01 can be separated from each other.

Since the first metal wire 10 and the second metal wire 20 are formed simultaneously by an etching process, the contact area between the first metal wire 10 and the second metal wire 20 can be maximized. Thus the contact resistance between the first metal wire 10 and the second metal wire 20 can be greatly reduced, and the wire width of the wiring structure 01 can be reduced.

In the method for manufacturing an array substrate provided by the embodiment of the invention, since the wiring structure 01 of the array substrate includes the first metal wire 10 and the second metal wire 20 stacked together, the increase in the resistance of the wiring structure 01 is small even if the wire width of the wiring structure 01 is reduced. On this basis, the contact resistance between the first metal wire 10 and the second metal wire 20 can be greatly reduced due to the direct contact of the first metal wire 10 and the second metal wire 20, thereby further reducing the resistance of the wiring structure 01. Thus, the embodiment of the invention can reduce the resistance of the wiring structure 01 while reducing the wire width of the wiring structure 01.

The above embodiments are only used for explanations rather than limitations to the present invention, the ordinary skilled person in the related technical field, in the case of not departing from the spirit and scope of the present invention, may also make various modifications and variations, therefore, all the equivalent solutions also belong to the scope of the present invention, the patent protection scope of the present invention should be defined by the claims.

1. A wiring structure, comprising: a first metal wire and a second metal wire disposed in a stack;
wherein the first metal wire and the second metal wire are in direct contact.

2. The wiring structure according to claim 1, wherein wire widths of the first metal wire and the second metal wire are the same, and projections of the first metal wire and the second metal wire in a plane perpendicular to the stacking direction are completely overlapped.

3. The wiring structure according to claim 2, wherein the wire width of the first metal wire and the wire width of the second metal wire are both 5˜50 μm.

4. The wiring structure according to claim 1, wherein materials of the first metal wire and the second metal wire are selected from at least one of single metal, alloy, and metal oxide.

5. An array substrate, comprising the wiring structure according to claim 1.

6. The array substrate according to claim 5, further comprising an insulating layer; wherein the first metal wire and the insulating layer are disposed in the same layer.

7. The array substrate according to claim 5, wherein the wiring structure is disposed in a peripheral region of the array substrate.

8. The array substrate according to claim 5, wherein the array substrate comprises a thin film transistor and a first electrode;
the first metal wire and the second metal wire are formed in synchronism with the thin film transistor; alternatively,
the first metal wire and the second metal wire are formed in synchronism with the thin film transistor and the first electrode.

9. The array substrate according to claim 5, wherein the array substrate comprises a thin film transistor, a pixel electrode and a common electrode;
the first metal wire and the second metal wire are formed in synchronism with the thin film transistor and the common electrode; alternatively,
the first metal wire and the second metal wire are formed in synchronism with the pixel electrode and the common electrode.

10. A display panel, comprising the array substrate according to claim 5.

11. A method for manufacturing an array substrate, comprising:
forming a first metal pattern, a region of the first metal pattern corresponding to a region where wiring structures are to be formed;
forming an insulating layer, and removing a portion of the insulating layer on the first metal pattern by an etching process; and
forming a second metal pattern, and forming a plurality of wiring structures by an etching process, each of the wiring structure comprising a first metal wire and a second metal wire stacked together.

12. The method for manufacturing an array substrate according to claim 11, wherein forming a first metal pattern comprises: forming a first metal layer, and performing an etching process on the first metal layer to form the first metal pattern.

13. The array substrate according to claim 5, wherein wire widths of the first metal wire and the second metal wire are the same, and projections of the first metal wire and the second metal wire in a plane perpendicular to the stacking direction are completely overlapped.

14. The array substrate according to claim 13, wherein the wire width of the first metal wire and the wire width of the second metal wire are both 5˜50 μm.

15. The array substrate according to claim 5, wherein materials of the first metal wire and the second metal wire are selected from at least one of single metal, alloy, and metal oxide.

16. The display panel according to claim 10, wherein wire widths of the first metal wire and the second metal wire are the same, and projections of the first metal wire and the second metal wire in a plane perpendicular to the stacking direction are completely overlapped.

17. The display panel according to claim 10, further comprising an insulating layer; wherein the first metal wire and the insulating layer are disposed in the same layer.

18. The display panel according to claim 10, wherein the wiring structure is disposed in a peripheral region of the array substrate.

19. The display panel according to claim 10, wherein the array substrate comprises a thin film transistor and a first electrode;
the first metal wire and the second metal wire are formed in synchronism with the thin film transistor; alternatively,
the first metal wire and the second metal wire are formed in synchronism with the thin film transistor and the first electrode.

20. The display panel according to claim 10, wherein the array substrate comprises a thin film transistor, a pixel electrode and a common electrode;
the first metal wire and the second metal wire are formed in synchronism with the thin film transistor and the common electrode; alternatively, the first metal wire and the second metal wire are formed in synchronism with the pixel electrode and the common electrode.
